(19) United States
(12) Patent Application Publication
(10) Pub. No.: US 2024/0221833 A1
(43) Pub. Date: Jul. 4, 2024

(54) SEMICONDUCTOR MEMORY DEVICE

(71) Applicant: SK hynix Inc., Icheon-si Gyeonggi-do (KR)

(72) Inventor: Sung Wook JUNG, Icheon-si Gyeonggi-do (KR)

(73) Assignee: SK hynix Inc., Icheon-si Gyeonggi-do (KR)

(21) Appl. No.: 18/345,839

(22) Filed: Jun. 30, 2023

(30) Foreign Application Priority Data
Dec. 30, 2022 (KR) 10-2022-0190277

(51) Int. Cl. G11C 16/04; H10B 43/10; H10B 43/27

(52) U.S. Cl. CPC G11C 16/0483; H10B 43/10; H10B 43/27

(57) ABSTRACT

Provided herein is a semiconductor memory device. The semiconductor memory device includes a first select line and a second select line disposed with a slit interposed therebetween, and a channel structure that is disposed in each of the first select line and the second select line and is adjacent to the slit. In the semiconductor memory device, the channel structure includes a sidewall facing the slit.

### CROSS-REFERENCE TO RELATED APPLICATION

The present application claims priority under 35 U.S.C. § 119(a) to Korean patent application number 10-2022-0190277 filed on Dec. 30, 2022, in the Korean Intellectual Property Office, the entire disclosure of which is incorporated by reference herein.

### BACKGROUND

### 1. Technical Field

Various embodiments of the present disclosure generally relate to an electronic device, and more particularly to a semiconductor memory device.

### 2. Related Art

Semiconductor memory devices are applied to small electronic devices as well as electronic devices in a variety of fields such as automobiles, medical cares, or data centers. Thus, demand for the semiconductor memory devices is increasing. Technical development of the semiconductor memory devices is in progress for miniaturization, large capacity, and high speed.

### SUMMARY

An embodiment of the present disclosure may provide for a semiconductor memory device. The semiconductor memory device may include a word line including a first area and a second area extending continuously from the first area, a first select line overlapping the first area of the word line, a second select line overlapping the second area of the word line, a slit provided between the first select line and the second select line, and a first channel structure disposed in each of the first select line and the second select line, and extending to penetrate the word line. The first channel structure may include a sidewall adjacent to the slit, with a groove being formed in the sidewall.

An embodiment of the present disclosure may provide for a semiconductor memory device. The semiconductor memory device may include a word line including a first area and a second area extending continuously from the first area, a first select line overlapping the first area of the word line, a second select line overlapping the second area of the word line, a slit provided between the first select line and the second select line, and a first channel structure disposed in each of the first select line and the second select line, and extending to penetrate the word line. Each of the first select line and the second select line may include a first protruding gate portion and a second protruding gate portion protruding toward the slit with the first channel structure therebetween.

### BRIEF DESCRIPTION OF THE DRAWINGS

FIGS. 1A and 1B are diagrams illustrating semiconductor memory devices according to embodiments of the present disclosure.

FIGS. 2A and 2B are sectional views illustrating first and second structures of the semiconductor memory devices according to embodiments of the present disclosure.

FIGS. 3A, 3B, and 3C are circuit diagrams illustrating memory blocks according to embodiments of the present disclosure.

FIG. 4 is a perspective view illustrating a semiconductor memory device according to an embodiment of the present disclosure.

FIGS. 5A and 5B are plan views illustrating the semiconductor memory device of FIG. 4.

FIGS. 6A and 6B are plan views illustrating embodiments of a first channel structure and a first slit.

FIGS. 7A, 7B, 7C, and 7D are sectional views illustrating a method of manufacturing a semiconductor memory device according to an embodiment of the present disclosure.

FIG. 8 is a block diagram illustrating an electronic system each including semiconductor memory devices according to embodiments of the present disclosure.

### DETAILED DESCRIPTION

The specific structural and functional descriptions disclosed herein are merely illustrative for the purpose of describing embodiments according to the concept of the present disclosure. The embodiments according to the concept of the present disclosure can be modified in various forms and replaced with other equivalent embodiments. Thus, the present disclosure should not be construed as limited to the embodiments set forth herein.

It will be understood that, although the terms “first,” “second,” etc. may be used herein to describe various elements, these elements should not be limited by these terms. These terms are only used to distinguish one element from another element, and the order or number of components is not limited by the terms.

Various embodiments of the present disclosure are directed to a semiconductor memory device that can improve the degree of integration and operational reliability.

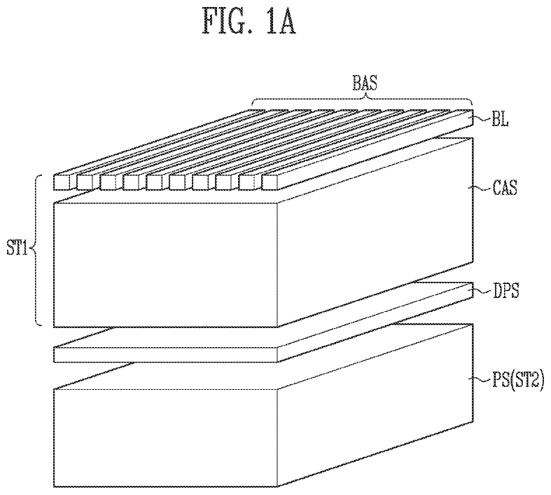

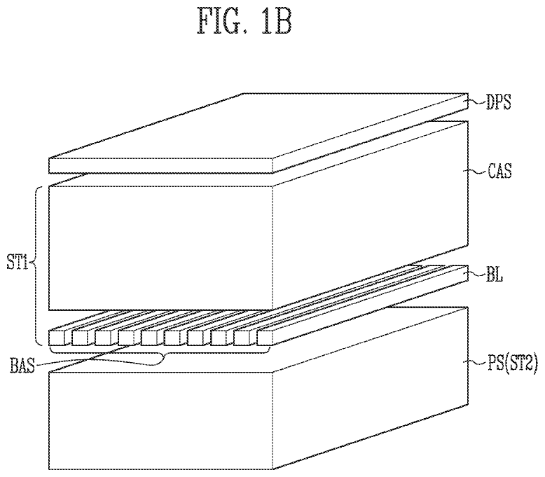

FIGS. 1A and 1B are diagrams illustrating semiconductor memory devices according to embodiments of the present disclosure.

Referring to FIGS. 1A and 1B, the semiconductor memory device may include a first structure ST1, a second structure ST2, and a doped semiconductor structure DPS. The first structure ST1 may include a cell array structure CAS and a bit line array structure BAS, and the second structure ST2 may include a peripheral circuit structure PS.

The bit line array structure BAS may include a plurality of bit lines BL.

The cell array structure CAS may be disposed between the bit line array structure BAS and the doped semiconductor structure DPS. The cell array structure CAS may include a memory block. The memory block may include a plurality of memory cell strings that are electrically connected to the bit line array structure BAS and the doped semiconductor structure DPS. Each memory cell string may include a channel structure extending from the doped semiconductor structure DPS toward the corresponding bit line BL. The channel structure may include a channel layer serving as a channel area of the memory cell string. Each memory cell string may include a plurality of memory cells stacked along the channel layer.

The peripheral circuit structure PS may be configured to perform a program operation for storing data in the memory cell, a read operation for outputting data stored in the memory cell, and an erase operation for erasing data stored in the memory cell. According to an embodiment, the peripheral circuit structure PS may include an input/output circuit, a control circuit, a voltage generation circuit, a row decoder, a column decoder, a page buffer, and the like. To be more specific, the peripheral circuit structure PS may include a plurality of transistors, a capacitor, a resistor, and the like.

The peripheral circuit structure PS may include an area overlapping the doped semiconductor structure DPS, the cell array structure CAS, and the bit line array structure BAS. The peripheral circuit structure PS may be adjacent to the doped semiconductor structure DPS as illustrated in FIG. 1A or may be adjacent to the bit line array structure BAS as illustrated in FIG. 1B.

The cell array structure CAS may be connected to the peripheral circuit structure PS via a plurality of select lines, a plurality of word line, the bit line array structure BAS, and the doped semiconductor structure DPS. Although not illustrated in the drawings, for electric connection, each of the first structure ST1 and the second structure ST2 may include at least one of a plurality of interconnections, a plurality of contacts, and a plurality of conductive bonding pads.

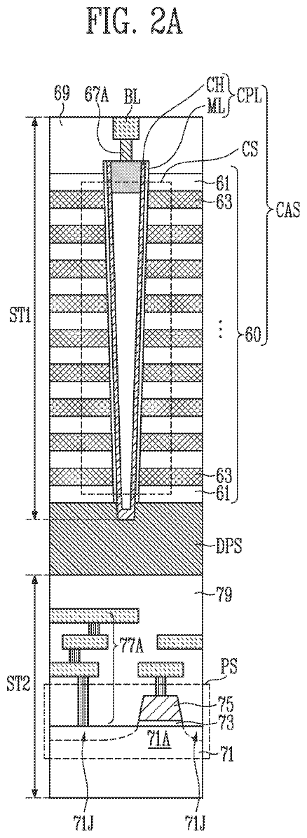

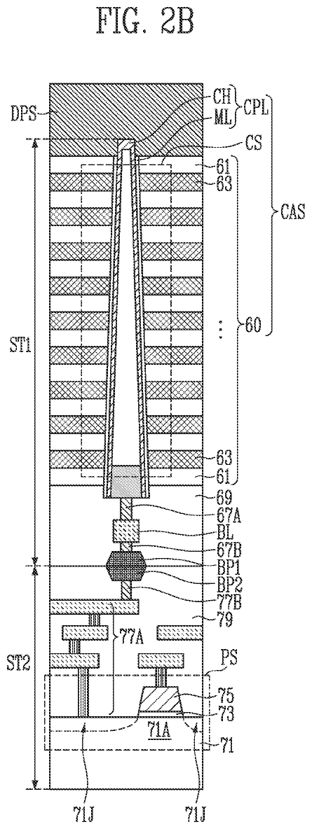

FIGS. 2A and 2B are sectional views illustrating the first and second structures of the semiconductor memory devices according to embodiments of the present disclosure.

Referring to FIGS. 2A and 2B, the first structure ST1 may include a cell array structure CAS, a first insulation structure 69, a bit line contact 67A, and a bit line BL. The cell array structure CAS may include a stacked body 60 between the doped semiconductor structure DPS and the bit line BL, and a cell plug CPL penetrating the stacked body 60.

The stacked body 60 may include a plurality of conductive layers 63 that are arranged to be spaced apart from each other in a vertical direction from the doped semiconductor structure DPS toward the bit line BL. The stacked body 60 may further include a plurality of insulating layers 61 arranged alternately with the plurality of conductive layers 63 in the vertical direction.

The cell plug CPL may include a channel layer CH, and a memory layer ML between the channel layer CH and the stacked body 60. The channel layer CH may be served as the channel area of the memory cell string CS. The channel layer CH may include an end connected to the doped semiconductor structure DPS. According to an embodiment, the channel layer CH may protrude into the doped semiconductor structure DPS compared to the memory layer ML, and the protruding end of the channel layer CH may be connected to the doped semiconductor structure DPS. The embodiment of the present disclosure is not limited thereto, and a connecting structure between the channel layer CH and the doped semiconductor structure DPS may be variously changed. The channel layer CH may be connected to the bit line BL via the bit line contact 67A. The bit line contact 67A and the bit line BL may be disposed in the first insulation structure 69.

The plurality of conductive layers 63 may be served as a select line and a word line provided as the gate electrodes of the memory cell string CS. According to an embodiment, the plurality of conductive layers 63 may be divided into a source select line adjacent to the doped semiconductor structure DPS, a drain select line adjacent to the bit line BL, and a plurality of word lines between the source select line and the drain select line.

The doped semiconductor structure DPS may include a doped area provided as at least one of a common source area and a well area. To this end, the doped semiconductor structure DPS may include at least one of n-type impurities and p-type impurities. According to an embodiment, the doped semiconductor structure DPS may include at least one of a first conductive doped area containing the n-type impurities as a majority carrier and a second conductive doped area containing the p-type impurities as a majority carrier. The first conductive doped area may be provided as the common source area, and the second conductive doped area may be provided as the well area. The embodiment of the present disclosure is not limited thereto, and the doped area of the doped semiconductor structure DPS may be variously designed.

The second structure ST2 may include a semiconductor substrate 71, a peripheral circuit structure PS, a second insulation structure 79, and a plurality of interconnections 77A. The peripheral circuit structure PS may correspond to the peripheral circuit structure described with reference to FIGS. 1A and 1B.

The semiconductor substrate 71 may include an active area 71A partitioned by an isolation layer (not illustrated). The peripheral circuit structure PS may include a transistor. The transistor may include a gate insulating layer 73 and a gate electrode 75 stacked on the active area 71A of the semiconductor substrate 71, and source/drain junctions 71J formed in the active area 71A on both sides of the gate electrode 75. The plurality of interconnections 77A may include sub-interconnections that are individually connected to the gate electrode 75 and the source/drain junctions 71J.

The semiconductor substrate 71 and the peripheral circuit structure PS may be covered with the second insulation structure 79, and the plurality of interconnections 77A may be disposed in the second insulation structure 79.

Referring to FIG. 2A, the process of forming the doped semiconductor structure DPS and the process of forming the first structure ST1 may be performed on the second structure ST2. According to an embodiment, after the doped semiconductor structure DPS is formed on the second structure ST2, the process of forming the first structure ST1 on the doped semiconductor structure DPS may be performed.

Referring to FIG. 2B, the process of forming the first structure ST1 and the process of forming the second structure ST2 may be individually performed. The first structure ST1 may further include a first contact 67B and a first conductive bonding pad BP1 disposed in the first insulation structure 69, and the second structure ST2 may further include a second contact 77B and a second conductive bonding pad BP2 disposed in the second insulation structure 79. The first structure ST1 and the second structure ST2 provided through the individual process may be connected to each other by a bonding process between the first conductive bonding pad BP1 and the second conductive bonding pad BP2. According to an embodiment, the doped semiconductor structure DPS may be provided after the bonding process is performed.

The first conductive bonding pad BP1 may be electrically connected to either the bit line BL or the conductive layers 63 via the first contact 67B to be connected to the memory cell string CS. The second conductive bonding pad BP2 may be electrically connected to any one of elements constituting the peripheral circuit structure PS via the second contact 77B. FIG. 2B representatively shows the transistor connected to the bit line BL. Specifically, the first conductive bonding pad BP1 connected to the bit line BL via the first contact 67B may be electrically connected to the second conductive bonding pad BP2 connected to the sub-interconnection of one of the plurality of interconnections 77A via the second contact 77B. Thus, the bit line BL may be electrically connected to the peripheral circuit structure PS via the first contact 67B, the first conductive bonding pad BP1, the second conductive bonding pad BP2, and the sub-interconnection.

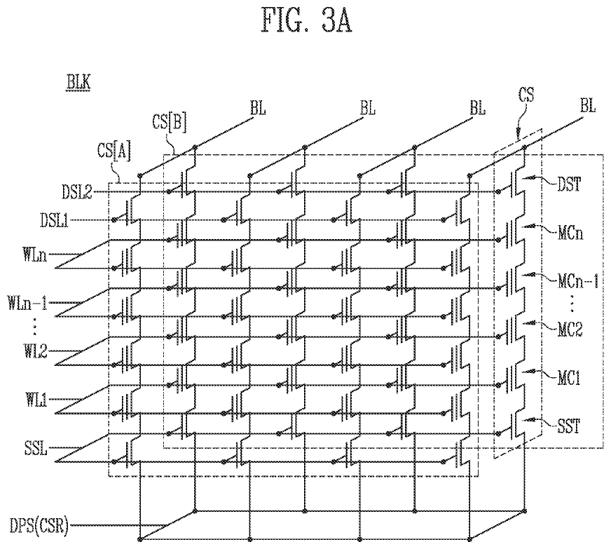

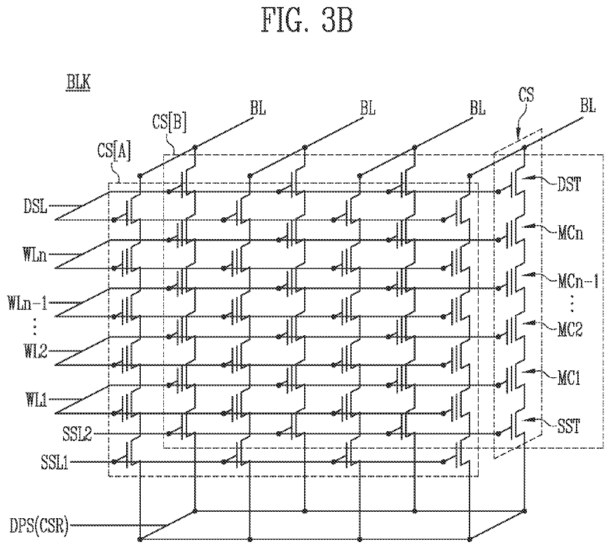

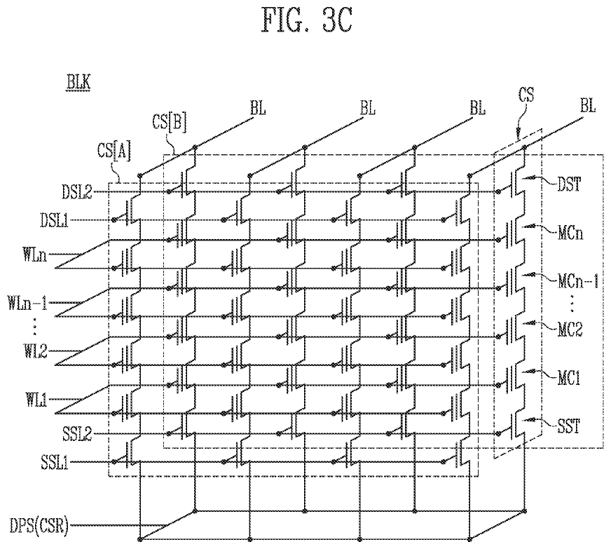

FIGS. 3A, 3B, and 3C are circuit diagrams illustrating memory blocks according to embodiments of the present disclosure.

Referring to FIGS. 3A to 3C, the memory block BLK may be included in the cell array structure CAS illustrated in FIGS. 1A and 1B. The memory block BLK may include a plurality of memory cell strings CS described with reference to FIGS. 2A and 2B.

Each memory cell string CS may include at least one source select transistor SST, a plurality of memory cells MC1 to MCn, and at least one drain select transistor DST. The plurality of memory cells MC1 to MCn may be connected in series between the source select transistor SST and the drain select transistor DST. The source select transistor SST, the plurality of memory cells MC1 to MCn, and the drain select transistor DST may be connected in series by the channel layer of the channel structure.

The plurality of memory cell strings CS may be connected in parallel to the common source area CSR of the doped semiconductor structure DPS. The common source area CSR may include the n-type impurities.

Each memory cell string CS may be connected to a corresponding bit line among the plurality of bit lines BL. The common source area CSR and the plurality of bit lines BL may be connected to the plurality of channel layers of the plurality of memory cell strings CS.

The plurality of memory cells MC1 to MCn of the memory cell string CS may be connected to the common source area CSR via the source select transistor SST. The plurality of memory cells MC1 to MCn of the memory cell string CS may be connected to a corresponding bit line BL via the drain select transistor DST.

The source select line SSL, SSL1 or SSL2, the plurality of word lines WL1 to WLn, and the drain select line DSL1, DSL2 or DSL may be served as the gate electrodes of the memory cell string CS. In detail, the source select line SSL, SSL1 or SSL2 may be served as the gate electrode of the source select transistor SST. The plurality of word lines WL1 to WLn may be served as the gate electrodes of the plurality of memory cells MC1 to MCn. The drain select line DSL1, DSL2 or DSL may be served as the gate electrode of the drain select transistor DST.

The plurality of memory cell strings CS may be arranged in a plurality of columns and a plurality of rows. In order to improve the integration degree of the semiconductor memory device, in an embodiment, the number of rows controlled by each of the word lines WL1 to WLn may be increased. In detail, the memory cell strings CS arranged in two or more rows may be controlled in common through each of the word lines WL1 to WLn. Here, the memory cell strings of different rows that are controlled in common through each of the word lines WL1 to WLn may be connected to the same bit line. In detail, the memory block BLK may include a first memory cell string CS[A] of a first row and a second memory cell string CS[B] of a second row, which are controlled in common by each of the word lines WL1 to WLn. The first memory cell string CS[A] and the second memory cell string CS[B] may be connected to the same bit line BL. The source select line SSL, SSL1 or SSL2 and the drain select line DSL1, DSL2 or DSL may be designed to select either of the first memory cell string CS[A] and the second memory cell string CS[B].

Referring to FIG. 3A, the first memory cell string CS[A] and the second memory cell string CS[B] may be connected to the same source select line SSL. The first memory cell string CS[A] and the second memory cell string CS[B] may be individually connected to the first drain select line DSL1 and the second drain select line DSL2 that are separated from each other. Thus, either of the first memory cell string CS[A] and the second memory cell string CS[B] may be selected, by selecting one of the plurality of bit lines BL and either of the first drain select line DSL1 and the second drain select line DSL2.

Referring to FIG. 3B, the first memory cell string CS[A] and the second memory cell string CS[B] may be connected to the same drain select line DSL. The first memory cell string CS[A] and the second memory cell string CS[B] may be individually connected to the first source select line SSL1 and the second source select line SSL2 that are separated from each other. Thus, either of the first memory cell string CS[A] and the second memory cell string CS[B] may be selected, by selecting one of the plurality of bit lines BL and either of the first source select line SSL1 and the second source select line SSL2.

Referring to FIG. 3C, the first memory cell string CS[A] and the second memory cell string CS[B] may be individually connected to the first drain select line DSL1 and the second drain select line DSL2 that are separated from each other. The first memory cell string CS[A] and the second memory cell string CS[B] may be individually connected to the first source select line SSL1 and the second source select line SSL2 that are separated from each other. Thus, the first memory cell string CS[A] may be selected by selecting the first source select line SSL1 and the first drain select line DSL1, and the second memory cell string CS[B] may be selected by selecting the second source select line SSL2 and the second drain select line DSL2.

Referring to FIGS. 3A to 3C, each bit line BL may be connected to the channel layer of the corresponding memory cell string CS. An operating voltage for pre-charging the channel layer of the memory cell string CS may be applied to the bit line BL.

The common source area CSR may be connected to the channel layer of the memory cell string CS. An operating voltage for discharging a channel potential of the memory cell string CS may be applied to the common source area CSR.

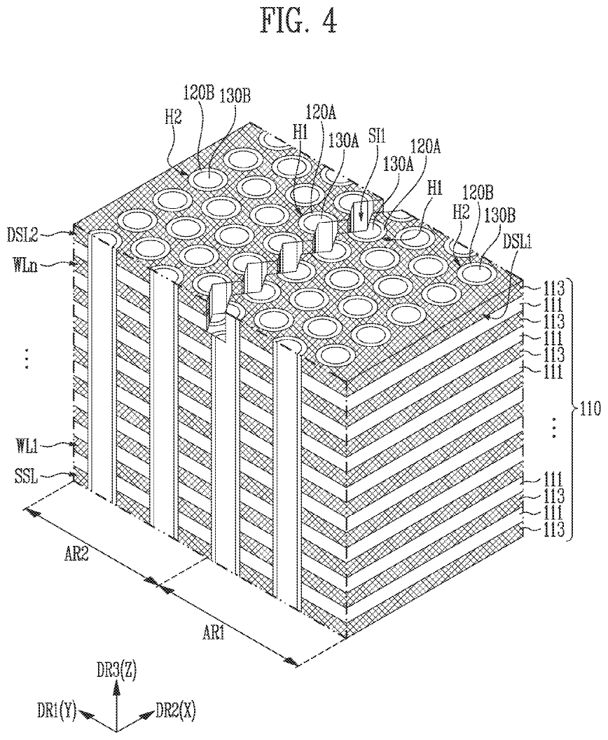

FIG. 4 is a perspective view illustrating a semiconductor memory device according to an embodiment of the present disclosure.

Referring to FIG. 4, the semiconductor memory device may include a stacked body 110 including a plurality of holes H1 and H2, a plurality of channel structures 130A and 130B, and a plurality of memory layers 120A and 120B. The plurality of holes H1 and H2 may be formed through the stacked body 110. The plurality of channel structures 130A and 130B may be disposed in the plurality of holes H1 and H2. The plurality of memory layers 120A and 120B may be disposed between the plurality of channel structures 130A and 130B and the stacked body 110.

The stacked body 110 may include a plurality of layers 111 and 113. Each layer 111 or 113 may have the shape of a plate extending in a first direction DR1 and a second direction DR2. The first direction DR1 may be defined as a row direction, while the second direction DR2 may be defined as a column direction. According to an embodiment, the first direction DR1 may correspond to a Y-axis direction, while the second direction DR2 may correspond to an X-axis direction.

The plurality of layers 111 and 113 may include a plurality of conductive layers 113 and a plurality of insulating layers 111. The plurality of conductive layers 113 may be arranged to be spaced apart from each other in a third direction DR3. The plurality of insulating layers 111 may be arranged alternately with the plurality of conductive layers 113 in the third direction DR3. The third direction DR3 may be defined as a direction in which an axis crossing the plate composed of each plate 111 or 113 is oriented. According to an embodiment, the third direction DR3 may correspond to a Z-axis direction.

The plurality of conductive layers 113 may be provided as the source select line SSL, SSL1 or SSL2, the plurality of word lines WL1 to WLn, and the drain select line DSL1, DSL2 or DSL, which are illustrated in FIGS. 3A to 3C. Among the plurality of conductive layers 113, at least one conductive layer may be separated into the first select line (e.g. DSL1) and the second select line (e.g. DSL2) by the first slit SI1. The plurality of conductive layers 113 illustrated in FIG. 4 representatively show the source select line SSL, the plurality of word lines WL1 to WLn, the first drain select line DSL1, and the second drain select line DSL2, which form a circuit illustrated in FIG. 3A. The first drain select line DSL1 and the second drain select line DSL2 may correspond to the first select line and the second select line separated by the first slit SI1. The embodiment of the present disclosure is not limited thereto. In an embodiment, among the plurality of conductive layers 113, a lowermost conductive layer may be separated into the first select line and the second select line by a slit. Here, the first select line and the second select line may correspond to the first source select line SSL1 and the second source select line SSL2 illustrated in FIG. 3B or FIG. 3C.

Each of the word lines WL1 to WLn may include a first area AR1 and a second area AR2 continuously extending from the first area AR1. The first area AR1 and the second area AR2 may be adjacent to each other in the first direction DR1. The first drain select line DSL1 may overlap the first area AR1 of each of the word lines WL1 to WLn, and the second drain select line DSL2 may overlap the second area AR2 of each of the word lines WL1 to WLn.

The first slit SI1 may be disposed between the first drain select line DSL1 and the second drain select line DSL2. The first slit SI1 may be filled with an insulating material.

The plurality of insulating layers 111 may include an insulating material such as a silicon oxide layer or a silicon oxynitride layer. The plurality of conductive layers 113 may include at least one of a doped semiconductor layer and a metal layer. The plurality of conductive layers 113 may further include a conductive metal nitride layer. The doped semiconductor layer may include a doped silicon layer. The metal layer may include tungsten, copper, molybdenum, etc. The conductive metal nitride layer may include titanium nitride, tantalum nitride, and the like.

The plurality of holes H1 and H2 may include a group passing through the first drain select line DSL1 and a group passing through the second drain select line DSL2. The plurality of holes H1 and H2 may extend to pass through the plurality of word lines WL1 to WLn and the source select line SSL. The plurality of holes H1 and H2 may be arranged in a line in the first direction DR1 to form a column and may be arranged in a line in the second direction DR2 to form a row. In order to improve the integration degree of the semiconductor memory device, in an embodiment, the plurality of holes H1 and H2 may be arranged in substantially a zigzag shape. Thus, centers of the holes arranged in neighboring rows might not be arranged in a line on a straight line extending along the first direction D1 but may be offset from each other.

In order to increase the arrangement density of the plurality of holes H1 and H2, a minimum distance between the plurality of holes H1 and H2 may be narrower than a minimum width of the first slit SI1. The first slit SI1 may be disposed between holes spaced apart from each other with a minimum distance therebetween. Thus, the first slit SI1 may be connected to some of the plurality of holes H1 and H2. The plurality of holes H1 and H2 may be divided into a first hole H1 and a second hole H2 with respect to the first slit SI1. The first hole H1 may be adjacent to the first slit SI1. The second hole H2 may be disposed further away from the first slit SI1 than the first hole H1. The first hole H1 may include a portion opened toward the first slit SI1 and a portion surrounded by the stacked body 110. The second hole H2 may have a closed shape surrounded by the stacked body 110.

The plurality of channel structures 130A and 130B may be divided into the first channel structure 130A and the second channel structure 130B with respect to the first slit SI1. The first channel structure 130A may be adjacent to the first slit SI1 and may be disposed in the first hole H1. In other words, the first channel structure 130A may be disposed in a corresponding select line among the first drain select line DSL1 and the second drain select line DSL2 at a location adjacent to the first slit SI1 and may extend to penetrate the plurality of word lines WL1 to WLn and the source select line SSL. The second channel structure 130B may be disposed further away from the first slit SI1 than the first channel structure 130A. The second channel structure 130B may be disposed in the second hole H2. In other words, the second channel structure 130B may penetrate a corresponding select line among the first drain select line DSL1 and the second drain select line DSL2 at a location away from the first slit SI1 and may extend to penetrate the plurality of word lines WL1 to WLn and the source select line SSL.

The plurality of memory layers 120A and 120B may be divided into the first memory layer 120A and the second memory layer 120B. The first memory layer 120A may be disposed between the first channel structure 130A and the stacked body 110, while the second memory layer 120B may be disposed between the second channel structure 130B and the stacked body 110. Each of the first memory layer 120A and the second memory layer 120B may be formed in a hollow type. The first channel structure 130A may be disposed in a hollow central area defined by the first memory layer 120A, and the second channel structure 130B may be disposed in a hollow central area defined by the second memory layer 120B. Each of the first memory layer 120A and the second memory layer 120B may include a gate insulating layer area corresponding to the source select line SSL, a gate insulating layer area corresponding to the first drain select line DSL1 or the second drain select line DSL2, and a data storage area corresponding to each of the word lines WL1 to WLn.

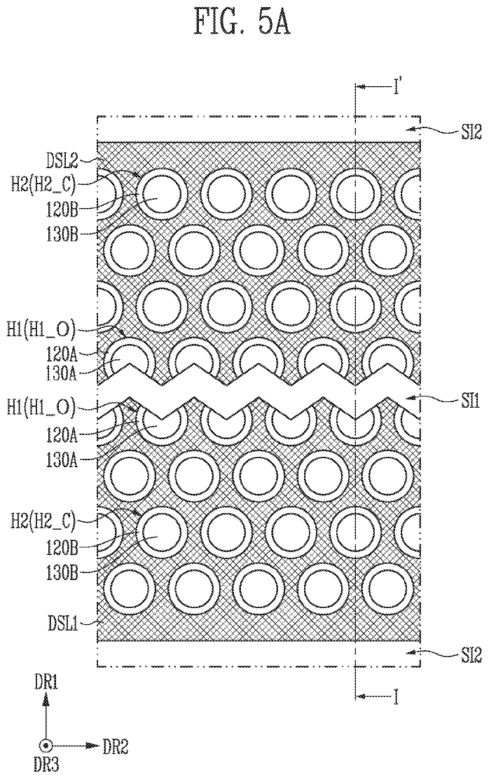

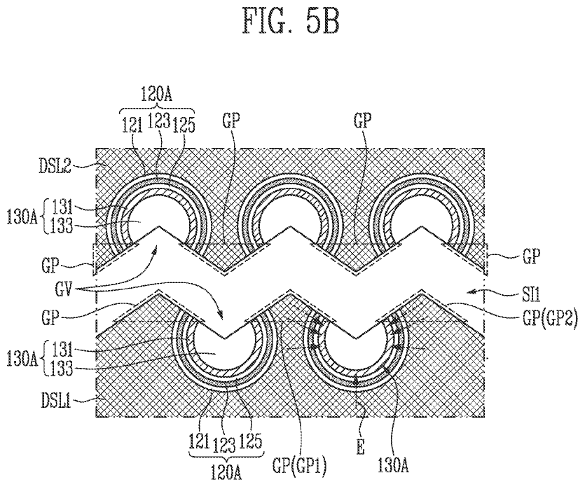

The stacked body 110 may be partitioned by the second slit SI2 illustrated in FIG. 5A.

FIGS. 5A and 5B are plan views illustrating the semiconductor memory device of FIG. 4. FIG. 5A shows a layout of the semiconductor memory device at a level where the first drain select line DSL1 and the second drain select line DSL2 illustrated in FIG. 4 are disposed, and FIG. 5B is an enlarged view showing the first slit SI1 of FIG. 5A and an area adjacent thereto. Hereinafter, components overlapping those described with reference to FIG. 4 will be described in brief or a detailed description thereof will be omitted.

Referring to FIG. 5A, the first drain select line DSL1 and the second drain select line DSL2 may be disposed on opposite sides of the first slit SI1. The first drain select line DSL1 and the second drain select line DSL2 may be disposed between the second slits SI2 partitioning the stacked body 110 illustrated in FIG. 4. Although not illustrated in the drawing, various internal structures of the second slit SI2 are possible. According to an embodiment, each second slit SI2 may be filled with an insulating material. According to an embodiment, a sidewall insulating layer and a conductive contact structure may be disposed in each second slit SI2. The sidewall insulating layer may extend along the sidewall of the stacked body 110 illustrated in FIG. 4. The conductive contact structure may include at least one of a doped semiconductor layer, a metal layer, and a conductive metal nitride layer. The doped semiconductor layer of the conductive contact structure may include at least one of n-type impurities and p-type impurities.

The first hole H1 described with reference to FIG. 4 may include an open hole pattern H1_O. The open hole pattern H1_O may be disposed at a level where the first drain select line DSL1 and the second drain select line DSL2 are disposed. The open hole pattern H1_O may be opened toward the first slit SI1 and may be connected to the first slit SI1. The second hole H2 described with reference to FIG. 4 may include a closed hole pattern H2_C. The closed hole pattern H2_C may be disposed at a level where the first drain select line DSL1 and the second drain select line DSL2 are disposed. The closed hole pattern H2_C may be surrounded by a corresponding select line among the first drain select line DSL1 and the second drain select line DSL2.

The first memory layer 120A may extend along the sidewall of the open hole pattern H1_O and may include an end that is cut by the first slit SI1. The first channel structure 130A may be disposed in the open hole pattern H1_O and may include a sidewall adjacent to the first slit SI1.

The second memory layer 120B and the second channel structure 130B may be disposed in the closed hole pattern H2_C. The second memory layer 120B and the second channel structure 130B may be surrounded by a corresponding select line among the first drain select line DSL1 and the second drain select line DSL2.

Referring to FIGS. 5A and 5B, each of the first memory layer 120A and the second memory layer 120B may include a blocking insulating layer 121, a data storage layer 123, and a tunnel insulating layer 125. The blocking insulating layer 121 may extend along the sidewall of the corresponding hole H1 or H2. The tunnel insulating layer 125 may extend along sidewalls of the corresponding holes H1 or H2 with the blocking insulating layer 121 interposed therebetween. The blocking insulating layer 121 may include an insulating material capable of blocking charges. The tunnel insulating layer 125 may include an insulating material capable of tunneling charges. The blocking insulating layer 121 may include an insulating layer having a dielectric constant higher than that of the tunnel insulating layer 125. The data storage layer 123 may be disposed between the blocking insulating layer 121 and the tunnel insulating layer 125. The data storage layer 123 may be formed of a material layer capable of storing changed data using Fowler Nordheim tunneling. According to an embodiment, the data storage layer 123 may be formed of a charge trap insulating layer, a floating gate layer, or an insulating layer containing conductive nano dots. A charge trap insulating layer may include a silicon nitride layer. The embodiments of the present disclosure are not limited thereto, and the data storage layer 123 may be formed of a material layer capable of storing information on the basis of an operating principle other than Fowler Nordheim tunneling. According to an embodiment, the data storage layer 123 may include a phase change material layer, a ferroelectric layer, and the like.

Referring to FIGS. 5A and 5B, each of the first channel structure 130A and the second channel structure 130B may include the channel layer 131. The channel layer 131 may extend along an inner wall of a corresponding memory layer 120A or 120B. The channel layer 131 may be formed of a semiconductor material that may be served as the channel area of the memory cell string. According to an embodiment, the channel layer 131 may include silicon (Si), germanium (Ge) or a mixture thereof. The channel layer 131 may be formed in a hollow structure as illustrated in the drawing. When the channel layer 131 is formed in the hollow structure, each of the first channel structure 130A and the second channel structure 130B may further include a doped capping layer (not illustrated) and a core insulating layer 133 disposed in the central area of the corresponding channel layer 131. The embodiments of the present disclosure are not limited thereto. According to an embodiment, the channel layer 131 may be formed in a pillar structure filling the central area of a corresponding hole H1 or H2.

Referring to FIG. 5B, the first channel structure 130A adjacent to the first slit SI1 may be used as the memory cell string. In order to improve the operational reliability of the memory cell string defined by the first channel structure 130A, in an embodiment, the shape of the first channel structure 130A and the shape of each of the first and second drain select lines DSL1 and DSL2 may be controlled. In detail, a groove GV may be formed in a sidewall of the first channel structure 130A facing the first slit SI1. Further, each of the first drain select line DSL1 and the second drain select line DSL2 may include a plurality of protruding gate portions GP protruding toward the first slit SI1. The above-described groove GV and the plurality of protruding gate portions GP may be defined along an outline of the first slit SI1.

The plurality of protruding gate portions GP may include a first protruding gate portion GP1 and a second protruding gate portion GP2 protruding toward the first slit SI1 with the first channel structure 130A therebetween. The first slit SI1 may be shaped to protrude toward the first channel structure 130A between the first protruding gate portion GP1 and the second protruding gate portion GP2.

The first channel structure 130A may include a select channel area defined at a level where the first drain select line DSL1 and the second drain select line DSL2 are arranged. According to an embodiment of the present disclosure, the select channel area of the first channel structure 130A is not formed in a gate all around (GAA) structure where each of the first select line DSL1 and the second select line DSL2 is placed on all sides of the first channel structure 130A. Even if the select channel area of the first channel structure 130A is not formed in the GAA structure, in an embodiment, the select channel area that is not controlled by the first drain select line DSL1 or the second drain select line DSL2 may be reduced through the groove GV. Thus, according to an embodiment of the present disclosure, a leakage current in the select channel area may be reduced. Further, even if the select channel area of the first channel structure 130A is not formed in the GAA structure, in an embodiment, the select channel area that is controlled by the first drain select line DSL1 or the second drain select line DSL2 may be increased by the first protruding gate portion GP1 and the second protruding gate portion GP2. According to an embodiment, an electric field E may be formed in the select channel area of the first channel structure 130A by a high voltage applied to the first drain select line DSL1. The electric field E may be formed even in the select channel area adjacent to the first slit SI1 by the first protruding gate portion GP1 and the second protruding gate portion GP2.

According to an above-described embodiment of the present disclosure, the leakage current in the select channel area may be reduced, thereby solving the operational disturbance of the semiconductor memory device and improving the operational reliability of the semiconductor memory device.

The groove GV and each protruding gate portion GP may be defined in various shapes. According to an embodiment, the groove GV and each protruding gate portion GP may be formed in substantially a V shape. According to an embodiment, the groove GV and each protruding gate portion GP may be formed to include an acute angle or right angle. According to an embodiment, the groove GV and each protruding gate portion GP may be formed to include an obtuse angle. Here, the first slit SI1 may be formed in substantially a zigzag shape along the groove GV and the sidewall of each of the first drain select line DSL1 and the second drain select line DSL2.

The first channel structure 130A may include a cross-sectional structure that is dug by the groove GV. According to an embodiment, the first channel structure 130A may have substantially a fan-shaped cross-sectional structure at a level where the first drain select line DSL1 and the second drain select line DSL2 are arranged. The fan-shaped cross-sectional structure may be a structure corresponding to a portion of a circle.

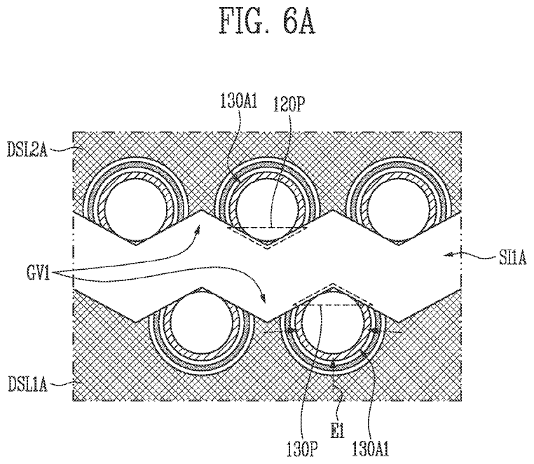

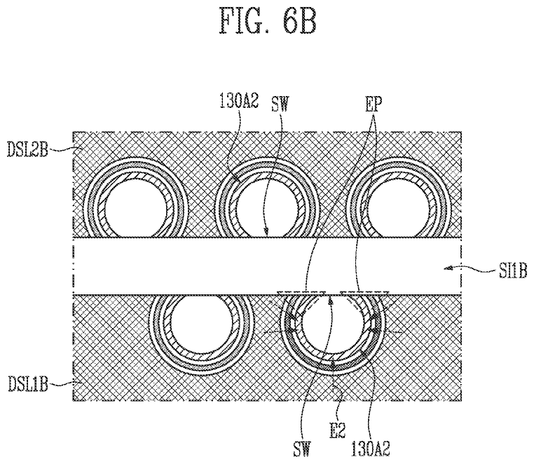

FIGS. 6A and 6B are plan views illustrating embodiments of the first channel structure and the first slit.

Referring to FIG. 6A, a first slit SI1A may extend between a first drain select line DSL1A and a second drain select line DSL2A in substantially a zigzag shape. Apart from the first slit SI1 illustrated in FIGS. 5A and 5B, the first slit SI1A may protrude toward a first drain select line DSL1A and a second drain select line DSL2A. Thus, a groove GV1 may be formed in the sidewall of each of the first drain select line DSL1A and the second drain select line DSL2A facing the first slit SI1A. Further, a first channel structure 130A1 may include a protruding channel portion 130P that protrudes toward the first slit SI1A.

It may be difficult for the protruding channel portion 130P to be controlled by a corresponding select line DSL1A or DSL2A, and a leakage current may occur in the protruding channel portion 130P. According to an embodiment, an electric field E1 may be formed in the select channel area of the first channel structure 130A1 by a high voltage applied to the first drain select line DSL1A. The electric field E1 may be directed toward the central area of the first channel structure 130A1. At this time, it is difficult for the electric field to be applied to the protruding channel portion 130P.

Referring to FIG. 6B, apart from the first slit SI1 illustrated in FIGS. 5A and 5B, a first slit SI1B may extend in a straight line between a first drain select line DSL1B and a second drain select line DSL2B. Thus, both ends EP of a first channel structure 130A2 facing the first slit SI1B may be flat along the sidewall SW of the first slit SI1B.

It may be difficult for both ends EP of the first channel structure 130A2 to be controlled by a corresponding select line DSL1B or DSL2B, and a leakage current may occur in both ends EP of the first channel structure 130A2. According to an embodiment, an electric field E2 may be formed in the select channel area of the first channel structure 130A2 by a high voltage applied to the first drain select line DSL1B. The electric field E2 may be directed toward the central area of the first channel structure 130A2. At this time, it is difficult for the electric field to be applied to both ends EP of the first channel structure 130A2.

The first channel structure 130A described with reference to FIGS. 4, 5A and 5B may be smaller in an area that is not controlled by the corresponding select line than the first channel structures 120A1 and 120A2 described with reference to FIGS. 6A and 6B. Therefore, according to various embodiments illustrated in FIGS. 4, 5A and 5B, the operational reliability of the semiconductor memory device may be improved.

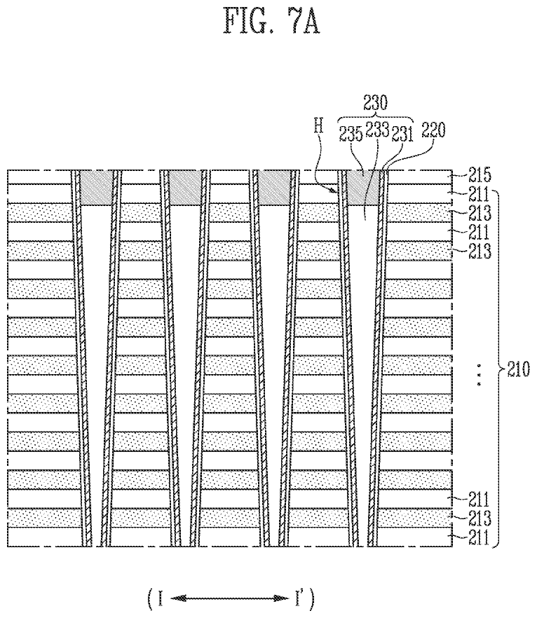

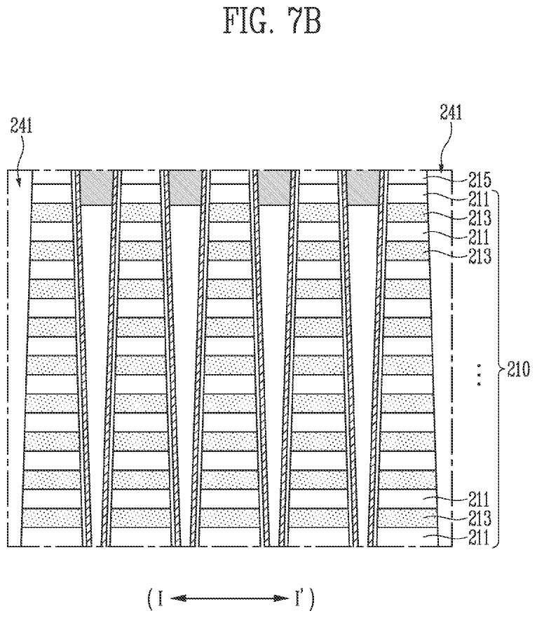

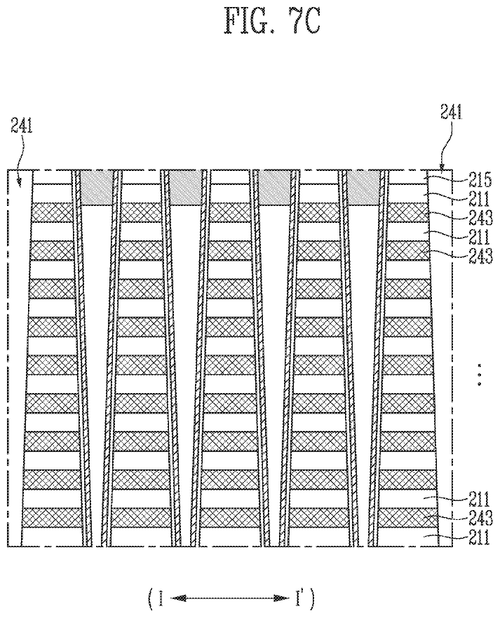

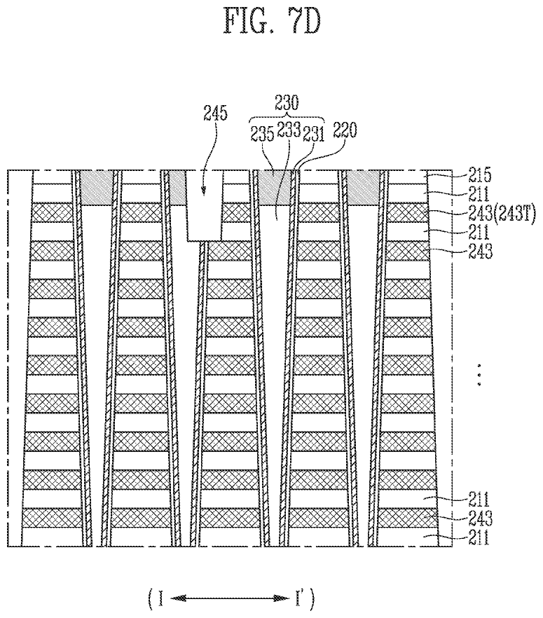

FIGS. 7A, 7B, 7C, and 7D are sectional views illustrating a method of manufacturing a semiconductor memory device according to an embodiment of the present disclosure. FIGS. 7A, 7B, 7C, and 7D are sectional views taken along line I-I′ of FIG. 5A to show a semiconductor memory device for each process step.

Referring to FIG. 7A, a pre-stacked body 210 may be formed on a lower structure (not illustrated). According to an embodiment, the lower structure may include the second structure ST2 and the doped semiconductor structure DPS described with reference to FIG. 2A. According to an embodiment, the lower structure may be a sacrificial substrate formed of a silicon wafer or the like. The sacrificial substrate may be subsequently replaced with the doped semiconductor structure DPS illustrated in FIG. 2B.

The pre-stacked body 210 may be formed on the lower structure according to various embodiments described above. The pre-stacked body 210 may include a plurality of first material layers 211 and a plurality of second material layers 213, which are alternately arranged.

The plurality of second material layers 213 may be formed of material having an etch selectivity with respect to the plurality of first material layers 211. According to an embodiment, the plurality of first material layers 211 may include an insulating material such as a silicon oxide layer or a silicon oxynitride layer, and the plurality of second material layers 213 may include a sacrificial insulating material such as a silicon nitride layer. The sacrificial insulating material may be subsequently replaced with a conductive material including at least one of a doped semiconductor layer, a metal layer, and a conductive metal nitride layer. According to an embodiment, the plurality of first material layers 211 may include a sacrificial material such as an undoped silicon layer, and the plurality of second material layers 213 may include a conductive material such as a doped silicon layer. The sacrificial material may be subsequently replaced with an insulating material such as a silicon oxide layer or a silicon oxynitride layer.

Unlike the above description, the plurality of first material layers 211 may be formed of an insulating material, and the plurality of second material layers 213 may be formed of a conductive material. According to an embodiment, the plurality of first material layers 211 may include a silicon oxide layer, a silicon oxynitride layer, etc., and the plurality of second material layers 213 may include at least one of a doped semiconductor layer, a metal layer, and a conductive metal nitride layer.

Subsequently, the method may include the step of forming the hole H in the pre-stacked body 210, the step of forming the memory layer 220 along the inner wall of the hole H, and the step of forming the channel structure 230 in the central area of the hole H that is opened by the memory layer 220.

The step of forming the hole H may include the step of forming a mask pattern (not illustrated) defining the planar shape of the hole H on the pre-stacked body 210, and the step of etching the plurality of first material layers 211 and the plurality of second material layers 213 using a mask pattern as an etch barrier. The hole H may pass through the plurality of first material layers 211 and the plurality of second material layers 213.

The memory layer 220 may include the blocking insulating layer 121, the data storage layer 123, and the tunnel insulating layer 125 illustrated in FIG. 5B.

The channel structure 230 may include the channel layer 231 extending along the inner wall of the memory layer 220. The channel layer 231 may include silicon (Si), germanium (Ge) or a mixture thereof. The channel layer 131 may be formed in a hollow structure or may be formed in a pillar structure filling the central area of the hole H. According to an embodiment, as illustrated in FIG. 7A, the channel layer 231 may be formed in a hollow structure. Here, the channel structure 230 may further include a core insulating layer 233 and a doped capping layer 235 disposed in the central area of the channel layer 231. The doped capping layer 235 may be formed of a semiconductor layer including at least one of n-type impurities and p-type impurities. According to an embodiment, the doped capping layer 235 may include the n-type impurities as a majority carrier. An end of the channel layer 231 adjacent to the doped capping layer 235 may be doped with the same impurities as the doped capping layer 235.

After forming the channel structure 230, the mask pattern may be removed. Subsequently, an insulating layer 215 covering the pre-stacked body 210 and the channel structure 230 may be formed.

Referring to FIG. 7B, a slit 241 may be formed to pass through the insulating layer 215 and the pre-stacked body 210. The slit 241 may correspond to the second slit SI2 illustrated in FIG. 5A. A subsequent process may vary depending on physical properties of the plurality of first material layers 211 and the plurality of second material layers 213. Hereinafter, a subsequent process will be described with an embodiment in which the plurality of first material layers 211 include an insulating material and the plurality of second material layers 213 include a sacrificial insulating material having an etch selectivity with respect to the insulating material.

Referring to FIG. 7C, the plurality of second material layers 213 of FIG. 7B may be replaced with the plurality of conductive layers 243 through the slit 241. Thus, an alternating stack structure of the plurality of first material layers 211 and the plurality of conductive layers 243 may be formed.

Referring to FIG. 7D, a slit 245 passing through the insulating layer 215 and at least an uppermost conductive layer 243T among the plurality of conductive layers 243 may be formed. The slit 245 may correspond to the first slit SI1 illustrated in FIG. 5A. While the slit 245 is formed, a portion of the channel structure 230 disposed on one side of the slit 245 may be etched. In this case, the shape of the slit 245 may be controlled so that the slit 245 is spaced apart from the channel structure 230 disposed on the other side of the slit 245.

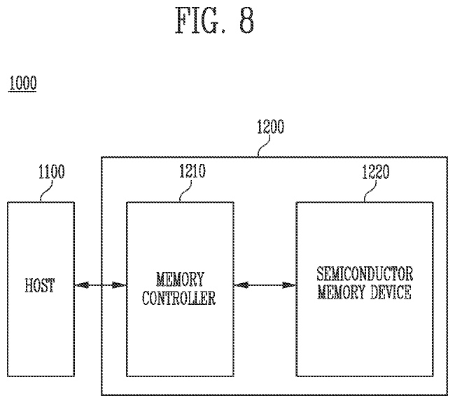

FIG. 8 is a block diagram illustrating an electronic system each including semiconductor memory devices according to embodiments of the present disclosure.

Referring to FIG. 8, an electronic system 1000 may be a computing system, a medical device, a communication device, a wearable device, a memory system, and the like. The electronic system 1000 may include a host 1100 and a storage device 1200.

The host 1100 may store data in the storage device 1200 or read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics (IDE) interface, a Firewire interface, a universal flash storage (UFS) interface, and a nonvolatile memory express (NVMe) interface.

The storage device 1200 may include a memory controller 1210 and a semiconductor memory device 1220. According to an embodiment, the storage device 1200 may be a storage medium such as a solid state drive (SSD) or universal serial bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a nonvolatile memory device. The semiconductor memory device 1220 may include the structure described with reference to FIGS. 4, 5A, and 5B. According to an embodiment, the semiconductor memory device 1220 may include the first select line and the second select line disposed with the slit therebetween, and the channel structure that is disposed inside each of the first select line and the second select line and adjacent to the slit. The shape of the slit may be controlled to define the outline of the channel structure or the outline of each of the first and second select lines. According to an embodiment, the slit may be formed to define the groove in the sidewall of the channel structure. In other words, the shape of the slit may be controlled such that each of the first and second select lines includes the protruding gate portion that protrudes toward the slit.

According to various embodiments of the present disclosure, a channel structure is disposed to be adjacent to a slit between a first select line and a second select line, thus increasing the arrangement density of the channel structure.

According to various embodiments of the present disclosure, the shape of a select line or the shape of a channel structure is designed to reduce a channel area that is not controlled by a select line.

According to an embodiment of the present disclosure, the arrangement density of a channel structure may be increased, so that the integration degree of a semiconductor memory device may be improved.

According to an embodiment of the present disclosure, a channel area that is not controlled by a select line may be reduced, so that the operational reliability of a semiconductor memory device may be improved.

What is claimed is:

1. A semiconductor memory device comprising:
a word line including a first area and a second area extending continuously from the first area;
a first select line overlapping the first area of the word line;
a second select line overlapping the second area of the word line;
a slit provided between the first select line and the second select line; and
a first channel structure disposed in each of the first select line and the second select line, and extending to penetrate the word line,
wherein the first channel structure comprises a sidewall adjacent to the slit, with a groove being formed in the sidewall.

2. The semiconductor memory device according to claim 1, wherein the groove is formed in substantially a V shape.

3. The semiconductor memory device according to claim 1, wherein each of the first select line and the second select line comprises a protruding gate portion protruding from each of opposite sides of the first channel structure toward the slit.

4. The semiconductor memory device according to claim 3, wherein the protruding gate portion is formed in substantially a V shape.

5. The semiconductor memory device according to claim 1, wherein the slit is formed in substantially a zigzag shape along a sidewall of each of the first select line and the second select line and the groove.

6. The semiconductor memory device according to claim 1, wherein the channel structure has substantially a fan-shaped cross-sectional structure at a level where each of the first select line and the second select line is disposed.

7. The semiconductor memory device according to claim 1, further comprising:
a second channel structure extending to penetrate each of the first select line and the second select line and to penetrate the word line, at a location farther from the slit than the first channel structure.

8. The semiconductor memory device according to claim 7, wherein the second channel structure is disposed inside a closed hole pattern surrounded by one of the first select line and the second select line.

9. The semiconductor memory device according to claim 1, wherein the groove is formed to include an acute angle or right angle.

10. The semiconductor memory device according to claim 1, wherein the groove is formed to include an obtuse angle.

11. A semiconductor memory device comprising:
a word line including a first area and a second area extending continuously from the first area;
a first select line overlapping the first area of the word line;
a second select line overlapping the second area of the word line;
a slit provided between the first select line and the second select line; and
a first channel structure disposed in each of the first select line and the second select line, and extending to penetrate the word line,
wherein each of the first select line and the second select line comprises a first protruding gate portion and a second protruding gate portion protruding toward the slit with the first channel structure interposed therebetween.

12. The semiconductor memory device according to claim 11, wherein each of the first protruding gate portion and the second protruding gate portion is formed substantially in a V shape.

13. The semiconductor memory device according to claim 11, wherein the slit protrudes toward the first channel structure between the first protruding gate portion and the second protruding gate portion.

14. The semiconductor memory device according to claim 11, wherein the slit is formed in substantially a zigzag shape along a sidewall of each of the first protruding gate portion and the second protruding gate portion and an outline of the first channel structure.

15. The semiconductor memory device according to claim 11, wherein the channel structure has substantially a fan-shaped cross-sectional structure at a level where each of the first select line and the second select line is disposed.

16. The semiconductor memory device according to claim 11, further comprising:
a second channel structure extending to penetrate each of the first select line and the second select line and to penetrate the word line, at a location farther from the slit than the first channel structure.

17. The semiconductor memory device according to claim 16, wherein the second channel structure is disposed inside a closed hole pattern surrounded by one of the first select line and the second select line.

18. The semiconductor memory device according to claim 11, wherein each of the first protruding gate portion and the second protruding gate portion is formed to include an acute angle or right angle.

19. The semiconductor memory device according to claim 11, wherein each of the first protruding gate portion and the second protruding gate portion is formed to include an obtuse angle.
